(19) United States
(12) Patent Application Publication
(10) Pub. No.: US 2026/0282241 A1
(43) Pub. Date: Sep. 17, 2026

(54) SEMICONDUCTOR PACKAGE WARPAGE AND ALIGNMENT MANAGEMENT

(71) Applicant: Arm Limited, Cambridge (GB)

(72) Inventors: Cameron Cole Nelson, Gilbert, AZ (US); George John Scott, Chandler, AZ (US); Javier DeLaCruz, San Jose, CA (US)

(21) Appl. No.: 19/082,058

(22) Filed: Mar. 17, 2025

(51) Int. Cl. H05K 3/34; H01L 21/48; H01L 23/00; H01L 23/498; H01L 23/544

(52) U.S. Cl. CPC H05K 3/3426; H10W 42/121; H10W 46/00; H10W 70/093; H10W 70/66; H10W 90/701; H05K 2203/0165; H05K 2203/0278; H05K 2203/041; H05K 2203/167; H10W 90/724

(57) ABSTRACT

An integrated circuit is attached to a substrate by separating them using one or more spacers and by a plurality of solder balls, and aligning them using at least one alignment element. A clamping mechanism biases the integrated circuit and substrate toward one another and coplanar to one another, and the integrated circuit, the substrate, and the clamping mechanism are heated to reflow the plurality of solder balls. The heat is removed, causing the plurality of reflowed solder balls to solidify, and the clamping mechanism is removed. The plurality of solder balls is underfilled, further securing the integrated circuit to the substrate.

### FIELD

The field relates to mounting integrated circuit devices, and more specifically to semiconductor package warpage and alignment management.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have multiple processor cores, graphics engines, artificial intelligence or neural network processors, cache memory, and a variety of other such functions on a single integrated circuit. The number of transistors on an integrated circuit therefore continues to grow, as does the power dissipated by an integrated circuit for a given process size (or device pitch size).

Such processors are often incorporated into products from handheld devices such as smartphones to large processors used in data centers, and are typically packaged or supported and protected in various ways before integration into an electronic device. Packages for integrated circuits such as these often perform several roles, from providing connection between the integrated circuit and a printed circuit board to thermal dissipation, environmental protection, and power support or regulation. Contacts on the integrated circuit may be attached to a substrate such as using flip chip, wire bond, or ball grid arrays, and the substrate may be coupled to a circuit board using a ball grid array, pin grid array, or similar connection scheme. The package may also support a heat sink or heat spreader, such as may be mounted in close thermal contact with the integrated circuit die using thermal paste or another thermal conductor. Devices such as capacitors, inductors, and the like may further be mounted to the substrate, supporting steady voltage regulation during periods of transition such as powering up or changing a performance mode of a processor core.

Some integrated circuit packages may have a variety of other features, such as metal enclosures or lids that protect the top of the integrated circuit from damage and that conduct heat to a heat sink or other thermal solution. Lids may also serve to spread heat from the integrated circuit die to a wider area in contact with a heat sink, but in some high performance environments may add too much resistance between the integrated circuit die and the thermal solution so may be omitted. Mounting the integrated circuit to the substrate often involves reflowing a solder ball array such as a flip chip ball grid array of solder balls between the integrated circuit package and the substrate, which can cause substantial warpage between the integrated circuit and the substrate such as where the coefficients of thermal expansion between the substrate and integrated circuit die are different. Some integrated circuit packages may therefore employ a stiffener, such as a metal loop attached around the perimeter of the substrate, to help the substrate resist warping as the integrated circuit package cools after solder reflow.

Larger integrated circuit dies and correspondingly larger substrates may exhibit some warping even with stiffeners, and differences in thermal coefficient of expansion between silicon and substrate material can result in warping even with stiffeners, lids, or other reinforcement measures. For reasons such as these, a need exists for improved management of warping when attaching or reflowing integrated circuit devices.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 shows an example integrated circuit assembly, as may be used to practice some example embodiments.

FIG. 2 shows a cross section of a clamping mechanism biasing a substrate toward a printed circuit board to flatten the substrate during reflow, consistent with an example embodiment.

FIG. 3 shows application of underfill to a clamped integrated circuit and printed circuit board assembly after reflow, consistent with an example embodiment.

FIG. 4 shows a cross section of a clamping assembly comprising a top biasing element biased against a printed circuit board, consistent with an example embodiment.

FIG. 5 shows a cross section of a clamping assembly comprising a bottom biasing element biased against a substrate area of a printed circuit board, consistent with an example embodiment.

FIG. 6 shows examples of spacers as may be used to maintain space between clamped elements during solder reflow, consistent with an example embodiment.

FIG. 7 shows a variety of alignment elements, consistent with an example embodiment.

FIG. 8 shows displacement of a fiberglass epoxy circuit board or substrate relative to a silicon integrated circuit during heating, consistent with an example embodiment.

FIG. 9 is a flow diagram of a method of using a clamping mechanism, spacers, and alignment elements to attach an electronic device to a substrate, consistent with an example embodiment.

FIG. 10 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. The integrated circuits upon which processor cores are formed may also contain graphics processors, such as are able to render graphical images at high speed, encode and decode various video formats, and the like. Sone processor integrated circuits also include artificial intelligence processing, such as neural network processors or the like that may be used to provide various functions such as chatbots, self-driving vehicles, and various other such functions. These increases in functionality result in significant increases in transistor count in the integrated circuit, which may add to the integrated circuit's physical size, power consumed, and number of external connections.

As the size of integrated circuits grows, packaging the integrated circuit may become increasingly challenging. The integrated circuit die is often attached to a substrate, such as using a flip-chip ball grid array of electrical connections between the integrated circuit and the substrate, such that the substrate can provide a wider pitch for an array of electrical connections to a printed circuit board such as using a ball grid array or pin grid array. The substrate in some examples may support components such as capacitors, inductors, and the like to support power delivery to the integrated circuit. The substrate may also support a lid configured to provide protection and rigidity to the integrated circuit package assembly, but lids are often omitted in high performance devices due to the thermal impedance they may introduce between the integrated circuit die and a heat sink or other thermal solution.

The integrated circuit die is typically mounted to a substrate using a solder reflow operation in which an array of solder balls deposited on electrical contacts of at least one of the integrated circuit die and the substrate are heated to the point of melting. This allows the solder balls to form a physical and electrical link between corresponding contacts on the integrated circuit die and the substrate, and surface tension in the melted solder balls typically ensures good alignment between the integrated circuit and the substrate while the solder balls cool and form a bond. But, the coefficient of thermal expansion of an integrated circuit die and a substrate are often different, and the integrated circuit assembly may warp as the substrate and the coupled integrated circuit die cool after reflow. Support structures such as lids may help resist warping, and stiffeners such as a ring of metal that may be attached near the perimeter of the substrate to provide extra rigidity such as for large integrated circuit packages that do not have a lid coupled to the substrate.

But, while packages of 10-20 mm square were once typical, modern semiconductor device packages may approach or exceed 100 mm square, significantly exacerbating the effects of coefficient of thermal expansion mismatches between semiconductor dies and substrates. Warping may often be observed as a semiconductor package warping up or away from a circuit board or other substrate at the corners, potentially resulting in omen or non-wet solder connections near the edges and bridging or shorts near the middle of an integrated circuit package.

Some examples presented herein therefore comprise methods and assemblies to reduce warping during alignment, and to preserve integrated circuit package alignment during mounting or reflow. The integrated circuit package may be clamped to bias the integrated circuit and substrate toward one another, and to flatten the integrated circuit package and substrate as solder balls physically and electrically connecting the integrated circuit package to the substrate are reflowed. In a further example, one or more alignment elements such as pins and corresponding holes on the integrated circuit package and substrate are used to keep the integrated circuit and substrate in alignment during the clamping and reflow operation, ensuring that the clamping mechanism does not displace the integrated circuit package relative to the substrate.

In one such example, a method of attaching an integrated circuit to a substrate comprises placing an integrated circuit on a substrate, the integrated circuit and the substrate separated by one or more spacers and by a plurality of solder balls. A clamping mechanism is applied to bias the integrated circuit and substrate toward one another and coplanar to one another, and the integrated circuit, the substrate, and the clamping mechanism are heated to reflow the plurality of solder balls, the clamping mechanism biasing the integrated circuit and the substrate together against the one or more spacers and coplanar during the reflow. The applied heat is removed to cause the plurality of reflowed solder balls to solidify, and the clamping mechanism is removed after the plurality of solder balls have solidified.

In another example, an integrated circuit mounting assembly comprises a top clamping element configured to engage an integrated circuit assembly, a bottom clamping element configured to engage a substrate, and a plurality of linking elements, each configured to engage the top clamping element and the bottom clamping element and to bias the top clamping element and the bottom clamping element toward one another, thereby biasing the integrated circuit assembly toward the substrate and flattening the integrated circuit assembly or the substrate, or a combination thereof.

In another example, A method of attaching an integrated circuit to a substrate comprises applying a clamping mechanism to bias the integrated circuit and substrate toward one another and coplanar to one another, and reflowing the integrated circuit to electrically and physically attach it to the substrate by heating the integrated circuit, the substrate, and the clamping mechanism.

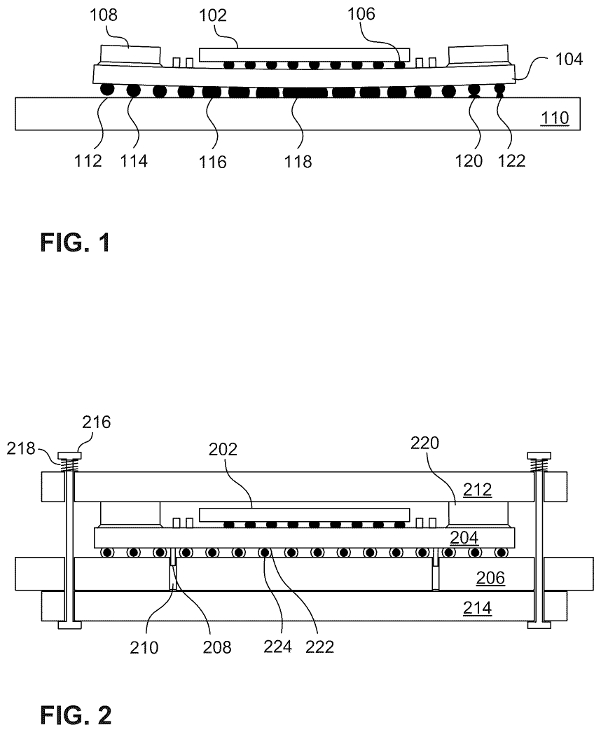

FIG. 1 shows an example integrated circuit assembly, as may be used to practice some example embodiments. Here, an integrated circuit die 102 is attached to a substrate 104, such as using solder balls 106 in a flip chip ball grid array. The substrate may have one or more stiffeners 108 mounted to the substrate using an adhesive such as epoxy, which may provide improved stiffness to the integrated circuit assembly during solder reflow mounting the integrated circuit die 102 to the substrate 104, may provide improved stiffness to the substrate 104 while reflowing a ball grid array of solder balls to mount the substrate to a printed circuit board 110, and/or may provide improved stiffness when the integrated circuit assembly heats up during integrated circuit operation. In some examples, a lid or other such device may similarly be attached to improve the stiffness of the integrated circuit package substrate, such as to resist thermal deformation due to differences in coefficient of thermal expansion between the integrated circuit die 102 and substrate 104 and/or printed circuit board 110 when using a reflow heating process to mount the integrated circuit die to the substrate or to mount the substrate to the printed circuit board.

The flip chip ball grid array shown at 106 and a ball grid array used to connect electrical contacts 112-122 to a printed circuit board may be may be known in the art as a ball grid array or BGA, and are commonly used as an electrical and physical interface between circuit components such as an integrated circuit package and a substrate, an interposer and a substrate, or the like. Ball grid arrays are often used to permanently mount devices such as microprocessors to circuit boards or substrates where a large number of contacts between the integrated circuit device and other circuitry are needed, such as where a flat package or dual in-line package are not sufficient. Further, a ball grid array interconnect typically has shorter traces between the solder balls in the array and the integrated circuit than other packages such as a flat package, potentially providing improved high speed performance.

Arrays of solder balls may be formed in some examples by forming metal pads and adhering solder balls to the pads on either the integrated circuit package, the substrate, or both. The arrays may be in a grid pattern, such as a square grid, diagonal grid, or other such grid pattern that is desirably uniform and repeatable or standardized, such that different entities such as integrated circuit manufacturers and product circuit board manufacturers can easily produce matching or interfacing grid arrays. Solder balls may be placed using automated equipment, and may be held in place by flux before being flowed or melted into adherence with the pads such as with a reflow oven or infrared heater. Surface tension may cause molten solder to hold an integrated circuit package in alignment with the substrate during a heating cycle, holding the integrated circuit package and substrate at a desired distance apart. When the solder balls cool, the solder balls form physical and electrical coupling between the integrated circuit and substrate.

The ball grid array as shown at 106 in FIG. 1 may be further used to mount multiple integrated circuit packages to an interposer, such as where multiple integrated circuit dies are mounted to the same substrate, but each integrated circuit die is mounted to its own interposer which is itself mounted to the substrate. The ball grid array, once reflowed to mount one layer to another, may further be filled with an underfill material filling gaps between solder balls in the ball grid array. This underfill may reduce thermal stress from heating and cooling between the integrated circuit die and the substrate such as due to differences in coefficient of thermal expansion, and may protect the integrated circuit die and the substrate from water intrusion or other contamination. In further examples, a protective package covering the top of the integrated circuit die may be employed to provide thermal conductivity to a heat sink for the integrated circuit die, and an array of external electrical contacts, and/or other such components may be employed.

The integrated circuit die 102 may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate in various examples may comprise a fiberglass and resin, organic laminate, ceramic, or other suitable material, and may contain within one or more conductive layers comprising various signal, power, and other electrical interconnects coupling the flip-chip bumps to ball grid array (BGA) solder balls, Land Grid Array (LGA) contact pads, Pin Grid Array pins, or other package electrical connections.

The substrate 104 in this example may be a material such as a resin, fiberglass reinforced resin, ceramic material, or the like, and in further examples may be built up of layers having electrical traces disposed between layers of fiberglass and resin, much like a printed circuit board but often at a higher density. The substrate's layers of electrical connections may be interconnected with vias, or vertical conductors that link electrical connections on one layer of the substrate with electrical connections on another layer. The substrate may also have electrical traces or pads on its exterior surfaces, such as to provide connection points for components such as capacitors and ball grid array solder ball pads.

Stiffener 108 may be attached to the substrate 104 using an adhesive 114 such as epoxy, and may be formed of metal, ceramic, resin, polymer, or other such material. In some embodiments, metal, ceramic, or metal-ceramic composites may be preferred for their relatively high stiffness, such as copper, steel, silicon carbide, aluminum silicon carbide, and the like. The stiffener may be configured to attach to the substrate around the edges of the substrate, both because the edges of the substrate may be the areas of greatest deflection and because the middle of the substrate may typically be occupied by integrated circuit die 102, capacitors, and other such components.

The ball grid array of solder balls 112-122 attaching the substrate 104 to printed circuit board 110 exhibit a variety of defects in the example of FIG. 1, due to warping or curvature of the substrate 104. This may be due to a coefficient of thermal expansion difference between the integrated circuit die 102 and the substrate 104, resulting in the substrate warping after reflowing (or heating) the flip-chip ball grid array 106 to attach the integrated circuit die to the substrate.

At 112, the solder ball attached to the substrate fails to make contact with a contact pad, such as a solder-coated copper trace, on the printed circuit board 110. This leaves an open electrical connection, and may cause improper operation of the integrated circuit. Solder ball 114 is a non-wet solder ball, and may connect with a contact pad on the printed circuit board but failed to flow to form a robust electrical connection and may be prone to failure such as during physical shock or load. Solder ball 116 is properly formed and reflowed, and represents a desired electrical and physical connection between the substrate and the printed circuit board. Solder balls 118 are located near the center of the warped substrate 104 and flowed together, resulting in a short between the electrical connections and likely rendering the integrated circuit inoperable. Solder ball connection 120 represents a “head-on-pillow” defect, in which solder bumps or balls on the substrate and printed circuit board are connected but failed to flow together to form a single solder ball. Solder ball connection 122 shows irregular stretching of a solder deposit on the printed circuit board to meet the solder ball attached to the substrate, and may be prone to failure under physical shock or load.

The solder ball defects shown at 112-114 and 118-122 are examples of defects that may form at least partially as a result of the substrate 104 and the printed circuit board 110 being out of plane with respect to one another, such as where the substrate is warped during integrated circuit attachment or reflow. Defects such as these may be remedied in some examples by biasing the substrate toward the printed circuit board during reflow, by use of spacers between the substrate and the printed circuit board, and/or by use of alignment pins to keep the substrate and printed circuit board properly aligned in the presence of a bias forcing the substrate and printed circuit board together.

FIG. 2 shows a cross section of a clamping mechanism biasing a substrate toward a printed circuit board to flatten the substrate during reflow, consistent with an example embodiment. The integrated circuit die 202, substrate 204, and printed circuit board 206 in the example of FIG. 2 are configured much like the example of FIG. 1, but with the addition of a clamping mechanism, alignment pins, and spacers to facilitate clamping the substrate and printed circuit board into a flattened configuration during reflow. In a more detailed example, a clamping mechanism is attached to bias the substrate and printed circuit board together, and is inserted into a reflow oven along with the substrate and printed circuit board.

The substrate 206 as shown in FIG. 2 has one or more alignment elements, such as alignment pins 208 attached to the substrate and corresponding alignment holes 210 formed within the printed circuit board. In an alternate example, the alignment pins 208 may be connected to the printed circuit board 206, and the holes 210 may be formed in the substrate 204. In some embodiments, two or more alignment pins may be employed to ensure that the substrate is aligned in two dimensions and does not rotate about a single alignment pin. In other examples, other alignment elements such as conical pins, standoffs or spacers with pins, balls, or other shames of alignment elements and corresponding mating features on a mating surface may be employed. Some such alignment features may be configured so that only a single alignment feature is used to align the substrate and printed circuit board in two dimensions, such as using a slot on the substrate corresponding to a protruding strip on the printed circuit board. Alignment features are added in some examples because clamping or biasing the substrate 204 and printed circuit board 206 together may overcome the surface tension forces of melted solder balls in the ball grid array that may otherwise be sufficient to align the substrate and circuit board with one another during reflow.

Once the substrate and the printed circuit board are assembled in an aligned position using the alignment features, a clamping assembly comprising a top clamping element 212, and bottom clamping element 214, and one or more linking elements such as clamping bolts 216 are assembled such that the clamping assembly biases the substrate 204 toward the printed circuit board 206, flattening the substrate and printed circuit board. The one or more clamping bolts may further include a spring 218, such as a helical metal spring, an elastic polymer, or other such spring mechanism to bias the top clamping element 212 toward the bottom clamping element 214 even should the top clamping element 212 move toward the bottom clamping element 214 when solder balls melt during reflow. The top clamping element 212 and the bottom clamping element 214 may be made of any material suitably strong to remain relatively flat and rigid during clamping and heating to 240° C. in a reflow oven, such as metal, polymer, fiberglass, carbon fiber, fiber-reinforced polymer, or the like.

Once solder balls 222 in the ball grid array are melted during reflow, the clamping force imparted by the clamping assembly may cause a traditional array of solder balls to squish undesirably flat, causing potential shorts as shown at 118 of FIG. 1. Some embodiments may therefore employ at least one spacer between the substrate 204 and the printed circuit board 206, such as a standalone spacer placed between the pins or a solid metal ball such as a copper ball 224 embedded within the solder balls 222 of the ball grid array. Because many metals such as copper melt at significantly higher temperatures than solder, solder balls with a copper metal center may be used to precisely maintain a desired spacing between the substrate and the printed circuit board during reflow. In a more detailed example, copper balls of a desired spacing are coated with a desired amount of copper and placed on either the substrate or the printed circuit board before alignment, assembly, and clamping of the example shown in FIG. 2, and may be held in place either with flux or by heating the solder-covered copper balls after placement to cause the solder to flow.

In the example of FIG. 2, the biasing force is applied to a bottom surface of the printed circuit board 206, and to the stiffeners mounted on the edges of the integrated circuit package substrate 204. In other examples, the biasing members may be adapted to provide biasing force in other ways, such as directly to the substrate, to only a portion of the printed circuit board, or in other ways that may bias the substrate and printed circuit toward one another and flatten the substrate and/or the printed circuit board. Although this example shows springs 218 used as biasing elements, other embodiments may include additional or different biasing elements, such as an elastic polymer configured to apply force from the clamping assembly to the printed circuit board, stiffener, substrate, or the like, such as to provide even distribution of force and to reduce the possibility of damage to the substrate or printed circuit board during clamping.

The example of FIG. 2 provides for alignment of the substrate 204 and printed circuit board 206 during reflow, provides a clamping mechanism that can bias the substrate and printed circuit board toward one another and flatten them during reflow, and provides spacers that maintain a desired separation between the substrate and the printed circuit board during reflow. The alignment and spacer elements may help reduce the chances of the biasing force from the clamping assembly displacing the substrate with respect to the printed circuit board, such as causing misalignment of the ball grid array contacts or causing the substrate and printed circuit board to be forced too close together. Such misalignments may cause open connections, short circuits between connections, and other such defects if alignment and spacing are not managed.

Although the example of FIG. 2 shows use of a clamping assembly to flatten the substrate 204 with respect to the printed circuit board 206 during reflow, the clamping assembly may be employed in other examples to flatten other elements or during other reflow operations, such as flattening substrate 204 when reflowing integrated circuit 202 to the substrate. In a further example, the flip-chip ball grid array attaching the integrated circuit 202 to the substrate 204 may be underfilled such as with epoxy before attaching the substrate 204 to a printed circuit board 206, preventing the integrated circuit from moving with respect to the substrate during subsequent reflow operations.

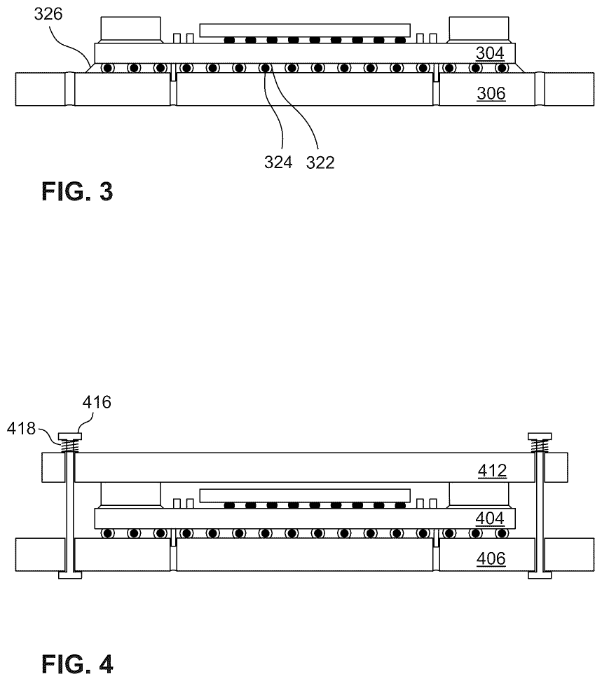

FIG. 3 shows application of underfill to a clamped integrated circuit and printed circuit board assembly after reflow, consistent with an example embodiment. In the example shown here, the clamping assembly of FIG. 2 has been removed after the reflow operation has melted the solder balls of the ball grid array joining the substrate 304 to the printed circuit board 306. The solder balls may melt again during a subsequent reflow operation, such as when populating the printed circuit board 306 with other components, allowing the substrate 304 to return to a warped shape and causing poor solder ball connections as reflected in the example of FIG. 1. The mounted integrated circuit package may therefore be underfilled using a material such as epoxy or thermoplastic as shown at 326, causing the substrate to adhere to the printed circuit board even during subsequent reflows.

The underfill material in some examples may flow between the substrate and the printed circuit board via capillary action, and in other examples may be injected between the substrate and the printed circuit board. The underfill material may be left to cure over time, or may be thermally cured in various embodiments. Once cured, the underfill material may also provide mechanical reinforcement to the solder balls 322 of the ball grid array, reducing the chances of at least a portion of the substrate 304 lifting off the printed circuit board 306 and increasing the life of the electronic device. The electronic device may be more resistant to shock, such as dropping the electronic device or printed circuit board, and may have improved ability to handle thermal stresses such as high operating temperatures when in use.

FIG. 4 shows a cross section of a clamping assembly comprising a top biasing element biased against a printed circuit board, consistent with an example embodiment. Here, a clamping assembly comprising a top biasing member 412 is biased toward printed circuit board 406 using biasing connectors such as biasing bolts 416 and biasing springs 418. The example of FIG. 4 differs from the example of FIG. 2 in that there is no bottom biasing member 214, but the biasing bolts 416 apply pressure directly to the printed circuit board.

In some examples, the holes in the printed circuit board that accommodate the biasing bolts 416 are heat sink or other thermal solution support holes. These holes may therefore be re-used to position and support a heat sink or other thermal solution for the mounted integrated circuit assembly during operation. Because these holes may be used to support a thermal heat dissipation solution that may have significant mass, such as a heat sink, these holes may already be configured to support a significant load and may not need a bottom biasing element to properly bias the substrate 404 toward the printed circuit board 406 during solder reflow. In a more detailed example, the printed circuit board may have a backing plate configured to support the heat sink attached or configured, such that the biasing bolts 416 may be attached to or through the backing plate in place of a bottom biasing element.

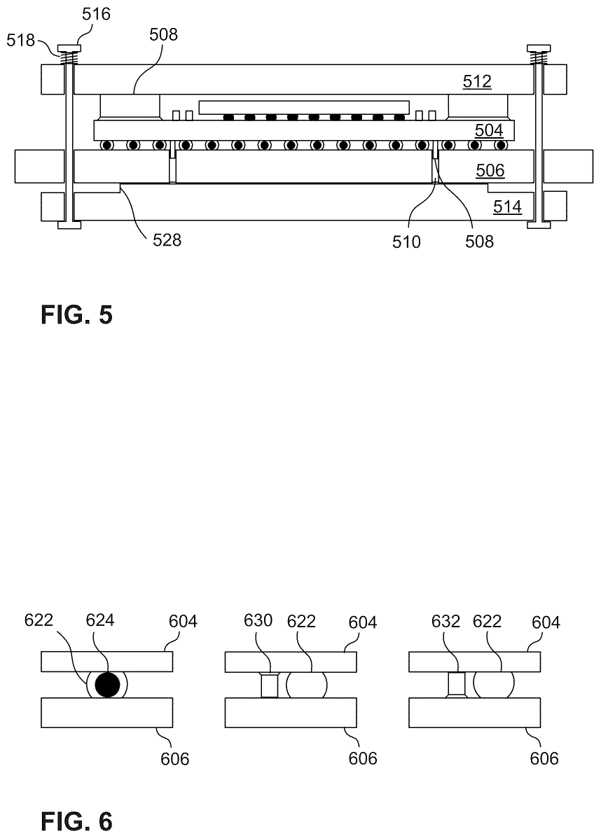

FIG. 5 shows a cross section of a clamping assembly comprising a bottom biasing element biased against a substrate area of a printed circuit board, consistent with an example embodiment. Here, a clamping assembly comprising a top clamping element 512 and a bottom clamping element 514 are biased toward one another using biasing bolts 516 and biasing springs 518, much as in the example of FIG. 2. The bottom biasing element 516 in this example is configured with a raised portion 528, configured to apply clamping pressure or bias to the printed circuit board in a limited area.

In a more detailed example, the area of the raised portion 528 of the bottom clamping element 514 may be approximately the same area as that covered by the substrate 504, or slightly smaller or slightly larger than the printed circuit board area covered by the substrate 504. In an alternate example, the raised portion 528 may correspond at least in part to an area on which pressure is applied to the substrate via the top clamping element 512, such as corresponding approximately and at least in part to the area covered by the stiffener 508. In other examples, pressure may be applied to one or more areas of the integrated circuit assembly, such as the stiffener 508 and/or the integrated circuit die 502, such as to apply more even pressure across the top clamping element 512. Because a silicon die may typically have a much lower coefficient of thermal expansion (typically around 2.6 ppm/° C.) than a printed circuit board or substrate (typically around 15 ppm/° C.), and because the greatest deviation due to thermal expansion during reflow may be likely to be observed near the edges of a substrate or other circuit board, clamping pressure may in some examples be focused on the perimeter of the substrate or other circuit board being reflowed.

Alignment elements such as alignment pins 508 and corresponding alignment holes 510 may therefore also be subject to greater displacement and misalignment the closer the are to the edge of a substrate or circuit board, and so may in some examples be placed away from the edges of a substrate, circuit board, or other element with a high coefficient of thermal expansion.

FIG. 6 shows examples of spacers as may be used to maintain space between clamped elements during solder reflow, consistent with an example embodiment. In the left assembly, a substrate 604 and a printed circuit board 606 are separated by a metal ball 624, such as a copper ball, that does not melt at typical solder reflow temperatures. The metal ball 624 is coated with solder 622, which melts during reflow and physically and electrically couples the substrate 604 to the printed circuit board 606. In a more detailed example, the assembly shown here may be reflowed in a reflow oven at approximately 240° C., and the metal ball 624 may be made of metal that melts at a temperature substantially above 240° C. In another example, another material may be used for the spacer ball 624, such as a conductive polymer, a conductive ceramic or metal-ceramic composite, or a nonconductive material.

In the middle assembly shown in FIG. 6, a substrate 604 and a printed circuit board 606 are separated by a spacer 630 that is attached to the substrate 604, such as using epoxy, solder, or another attachment means. In some examples, it may be desirable for the spacer 630 to be attached to the substrate in such a way that it does not become detached during reflow, such as using an epoxy, mechanical fastener, or other means that maintains rigid attachment during solder reflow. The solder ball 622 of the middle example does not have a copper or other solid metal core, but is a traditional solder ball comprising essentially solder.

In the circuit board assembly shown on the right of FIG. 6, the substrate 604 is spaced from the printed circuit board 606 using one or more spacers 632 attached to the printed circuit board. This example differs from the middle example using spacer 630 only in that the spacer 632 is attached to the printed circuit board rather than to the substrate. In some examples, it may be desirable to attach the spacer to only one of the substrate or the printed circuit board, such as where removal of the substrate may be desired at a future time.

In another example, the spacers 630 and 632 of the examples of FIG. 6 may be conductive spacers attached with solder, such as where no provision has been made for locating the spacers within the ball grid array such as leaving a gap in the pattern of solder balls to accommodate a spacer. The spacers in one such example may be used to form an electrical connection between the substrate 604 and the printed circuit board 606, such as by being soldered or reflowed to the substrate and to the printed circuit board.

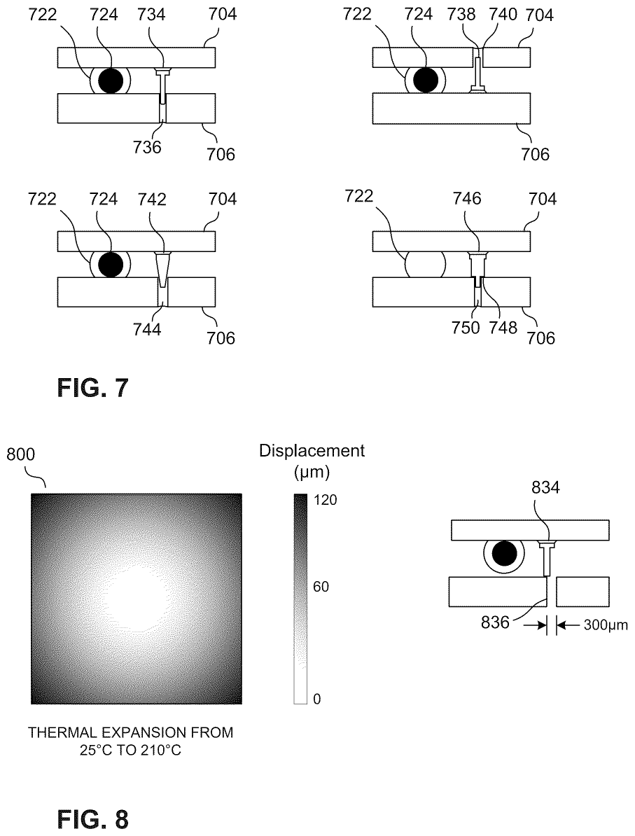

FIG. 7 shows a variety of alignment elements, consistent with an example embodiment. In the top left example, a solder ball 722 has a metal core 724, such as a nickel-plated copper core, which has been subsequently coated with solder. The metal core 724 serves as a spacer in this example, and determines the space between the substrate 704 and the printed circuit board 706 after reflow. To ensure proper alignment of the ball grid array electrical contacts on the substrate and the printed circuit board, an alignment pin 734 is attached to the substrate, such as with an epoxy adhesive. The alignment pin is configured to mate with a corresponding alignment hole 736 on the printed circuit board, which in various examples may be larger than the diameter of the alignment pin to a degree dependent on the desired alignment accuracy.

In the top right example of FIG. 7, a solder ball 722 and metal core 724 again serve as a spacer and to electrically and physically connect the substrate 704 to the printed circuit board after reflow, and an alignment pin 738 serves to hold the substrate and printed circuit board in alignment by mating with an alignment hole 740. The alignment pin 738 in this example is attached to the printed circuit board, and a corresponding mating hole 740 is formed in the substrate. The hole 740 in this example is shown larger in size than the hole 736 in the top right example, reflecting a greater tolerance and allowing for greater thermal displacement during reflow without bending or stressing the alignment pin 738.

The bottom left example in FIG. 7 shows a solder ball 722 and metal core 724 again serving as a spacer and providing electrical and physical connection between the substrate 704 and the printed circuit board 706, but alignment pin 742 mounted to the substrate is tapered to self-center within the alignment hole 744 in the printed circuit board. This may be desirable to help bring the substrate and printed circuit board into alignment before reflow, and may provide more precise alignment despite using a relatively large hole 744 than other examples such as the top left example of FIG. 7. In a further example, the alignment element 742 may have some flexibility, such a being made of an elastic polymer, to permit some movement or displacement of the substrate relative to the printed circuit board during solder reflow. This may be particularly desirable when the alignment feature such as alignment pins and corresponding holes are used to align materials with significantly different coefficients of thermal expansion, such as mounting an integrated circuit die to a substrate or printed circuit board.

The lower right example in FIG. 7 shows a normal solder ball 722, along with an alignment pin 746 that includes a shoulder portion 748 that is too large to fit in a corresponding alignment hole 750. This enables the alignment pin 746 to serve as both an alignment element and as a spacer, replacing other spacer mechanisms such as metal balls 724 seen in the other examples of FIG. 7. As with the top two examples of FIG. 7, the hole 750 may be sized in conjunction with the diameter of the alignment pin 746 to provide a desired degree of tolerance or precision in alignment, and the shoulder portion of the pin 746 may be sized sufficiently larger than the hole 750 to provide the desired spacing between substrate 704 and printed circuit board 706.

FIG. 8 shows displacement of a fiberglass epoxy circuit board or substrate relative to a silicon integrated circuit during heating, consistent with an example embodiment. FIG. 8 shows generally in the graph 800 how as a substrate expands as it is heated from room temperature to 240° C. across an example integrated circuit die area of 100 mm². Displacement due to the coefficient of thermal expansion of the substrate or circuit board is measured from the center of the square area, as reflected by the white color (and as defined in the shading legend to the right of the graph). The four corners of the 100×100 mm area are black, which represents the maximum observed displacement of 120 μm, and the displacement generally increases as a function of distance from the middle of the area shown.

If the displacement in the area of an alignment element such as a pin, shown at 834, is greater than the movement allowed by the corresponding mating hole, the alignment element may not fit in the hole or may be bent or broken during reflow. In the example shown here, a 100 μm alignment pin as shown at 834 may be displaced up to 100 μm relative to the alignment hole and still fit in a 300 μm alignment hole 836, but displacement of greater than 100 μm may cause the alignment pin to not align with the corresponding hole. It may therefore be desirable to have alignment pins or other such alignment elements within a limited distance of one another, limiting the displacement of alignment features with one another when the assembly is heated, such as during solder reflow. Alignment pins in other examples may align within other operable ranges or tolerances, such as within 50 microns, 200 microns, or the like. In alternate examples, the allowable displacement may be defined in terms of contact pitch, such as the center-to-center distance of adjacent solder balls in a ball grid array. In some such examples, alignment features such as alignment pins may be configured to align within one-quarter, one-third, or one-half the pitch between adjacent solder balls or other such electrical contacts in a grid array.

It may be desirable to have at least two alignment features in some examples, such as where the alignment features are pins, so that the substrate does not spin about the alignment feature relative to the printed circuit board. A second alignment feature such as a pin may be sufficient to restrict such movement, and the distance between such alignment features may be selected based on factors such as thermal displacement of a substrate, circuit board, die, or the like between the selected alignment elements and the desired alignment precision. In another example, a single alignment feature extending along at least one dimension perpendicular to the alignment pin or other alignment feature may provide sufficient alignment and limit rotation or other such displacement about the alignment feature, such as using a tab that extends in a direction perpendicular to the plane of the substrate or printed circuit board that mates with a corresponding slot.

The allowable displacement on a substrate, circuit board, or die being electrically and physically joined to another component may be at least partially dependent on displacement from one or more other alignment features. In one such example, two alignment pins near the same corner may be within displacement tolerance of one another even when heated due to the small distance between them, but the misalignment observed at the opposite corner may be double what it would be if the same alignment pins were located near the center of the example substrate or die mating area due to the increased distance from the alignment features. It may therefore be desirable in some embodiments to place alignment pins or other such alignment features away from the corners of the mating area as represented by the graph shown at 800, and nearer the center. For reasons such as these, some example embodiments may place alignment features near the center of a mating area and/or on opposite sides of the center of the mating area, such as placing alignment pins on a 100 mm² ball grid array within 30 mm to either side of the center of the ball grid array.

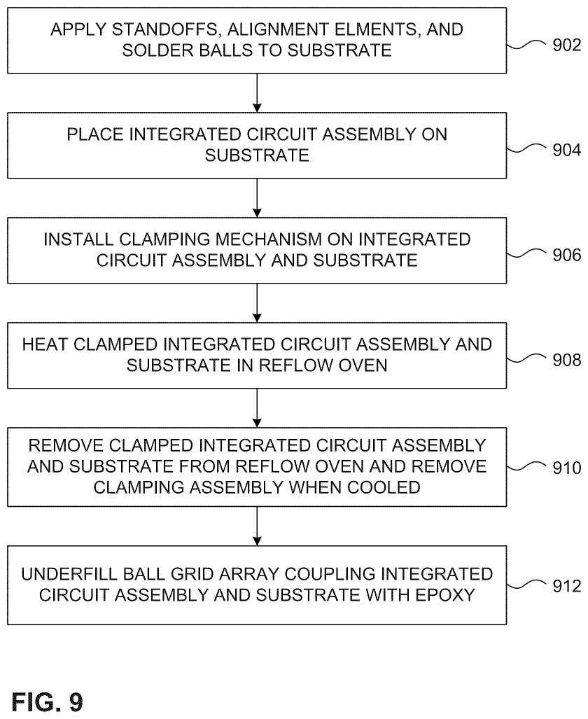

FIG. 9 is a flow diagram of a method of using a clamping mechanism, spacers, and alignment elements to attach an electronic device to a substrate, consistent with an example embodiment. The devices being attached may in various examples comprise integrated circuits, substrates, printed circuit boards, and/or other such devices. The attachment mechanism in various examples may comprise a ball grid array, variants such as a flip chip ball grid array or fine pitch ball grid array, or other attachment mechanism. The devices may in some examples be prone to warping, such as due to different coefficients of thermal expansion causing warping such as when the solder balls forming a ball grid array are cooling, such that the assembly of devices may benefit from various clamping or flattening, alignment, and/or spacing elements.

In the example of FIG. 9, an electronic device such as an integrated circuit and a substrate are being attached using a ball grid array of solder balls. The integrated circuit may be formed on a silicon substrate having a coefficient of thermal expansion of approximately 2.6 parts per million per degree Celsius, while the substrate may be fiberglass and epoxy resin board having a coefficient of thermal expansion of approximately 15 parts per million per degree Celsius. This difference in coefficient of thermal expansion may cause the substrate to expand significantly more than the integrated circuit when heated in a solder reflow oven to 240° Celsius to physically and electrically join the parts using a ball grid array of solder balls, and to shrink more than the integrated circuit when cooling after reflow. This can cause the substrate to warp with respect to the integrated circuit during cooling, making alignment of the substrate with another device and electrical connection between the devices such as a printed circuit board, a socket, or the like less reliable.

At 902, one or more alignment elements are applied to a substrate, along with a plurality of spacers or standoffs. The alignment elements and spacers may be the same elements, such as shown in the lower right example of FIG. 7, or may be discrete elements such as alignment pins and spacer pins or spacer solder-coated metal balls. The solder-coated metal balls may be used in place of solder balls to form the ball grid array electrical and physical connections in a more detailed example, as shown in the examples of FIGS. 2-8. The integrated circuit assembly is then placed on the substrate at 904, aligning the alignment elements such as holes, pins, slots, or the like on the integrated circuit assembly with corresponding mating alignment elements on the substrate. The integrated circuit assembly in various examples may be an integrated circuit die, an integrated circuit on a substrate, or other such assembly, while the substrate may be a printed circuit board or other such substrate.

A clamping mechanism is installed on the integrated circuit assembly and substrate at 906, biasing the integrated circuit assembly and substrate toward one another and into a flattened position. In a more detailed example, the clamping mechanism may apply force on the edges of the integrated circuit assembly, such as on the edges of a substrate or stiffener of the integrated circuit assembly, and on at least a portion of the substrate opposite the integrated circuit assembly. The substrate in some examples may have holes for mounting a thermal dissipation solution, such as heat sink or heat exchanger mounting holes in a printed circuit board, and the clamping mechanism may make use of thermal dissipation solution mounting holes to assembled the clamping mechanism and/or to bias elements of the clamping mechanism together (such as is shown in the examples of FIGS. 2-5).

Once the clamping mechanism has been installed, the integrated circuit assembly, substrate, and clamping mechanism are placed in a reflow oven at 908. The reflow oven may heat the components in the oven to a sufficient temperature to cause solder to flow, such as 240° C., forming a physical and electrical connection between the integrated circuit assembly and the substrate. The clamping mechanism in some embodiments may have one or more resilient members such as a spring or elastic polymer that are operable to maintain a biasing force on the integrated circuit assembly and the substrate after some movement, such as after the solder outer layer on solder-coated copper balls in the ball grid array have flowed due to heating.

Once the solder reflow process is complete the clamped assembly may be removed from the reflow oven and allowed to cool, solidifying the ball grid array of solder balls. The solder balls may be strong enough once cooled to physically keep the integrated circuit assembly and substrate from warping with respect to one another, but may lose their physical strength if reheated such as if further reflow operations for the substrate are needed. The ball grid array may be underfilled with epoxy at 912, to further solidify the mechanical bond between the integrated circuit assembly and the substrate such as during subsequent reflow operations, and to protect the ball grid array from moisture or other contaminants.

The examples presented herein illustrate how use of alignment features and spacers may help ensure that a die or substrate are positioned as desired when being mounted to a substrate or printed circuit board using a ball grid array reflow, particularly when used with a clamping mechanism to ensure that the reflowed assembly is flat and that the ball grid array comprises sound physical and electrical connections across the array. Design or implementation choices may include the clamping force needed, placement of alignment pins or other alignment features and the acceptable alignment tolerance, the desired spacing between the elements being joined with the ball grid array reflow, and the like. Because clamping as shown in the examples of FIGS. 2-5 may introduce significant stress to the integrated circuit substrate or printed circuit board, the force applied may be carefully chosen based at least in part on a tradeoff between applying sufficient force to achieve the desired flatness but not enough force to cause undesired stress or damage. Underfilling or edge filling a ball grid array-mounted device once it has cooled may serve to prevent the device from lifting off or warping if the device is subjected to another reflow or heats appreciably during operation, and may be achieved using epoxy or another suitable material. In some embodiments, the clamping mechanism may employ heat sink holes or other thermal solution mounting holes to secure and/or align the clamping mechanism with respect to a printed circuit board, substrate, or other such component.

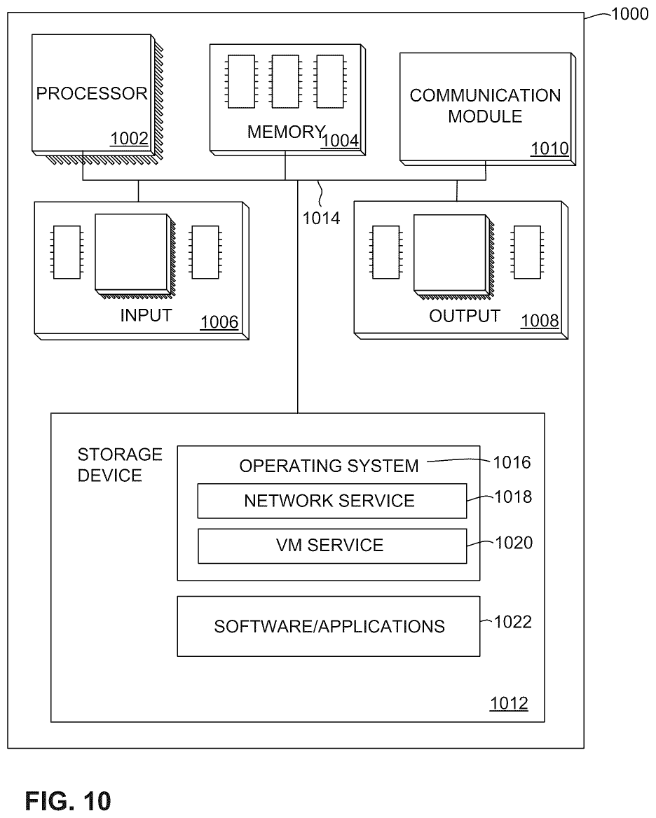

FIG. 10 shows a block diagram of a general-purpose computerized system, consistent with an example embodiment. FIG. 10 illustrates only one particular example of computing device 1000, and other computing devices 1000 may be used in other embodiments. Although computing device 1000 is shown as a standalone computing device, computing device 1000 may be any component or system that includes one or more processors or another suitable computing environment for executing software instructions in other examples, and need not include all of the elements shown here.

As shown in the specific example of FIG. 10, computing device 1000 includes one or more processors 1002, memory 1004, one or more input devices 1006, one or more output devices 1008, one or more communication modules 1010, and one or more storage devices 1012. Computing device 1000, in one example, further includes an operating system 1016 executable by computing device 1000. The operating system includes in various examples services such as a network service 1018 and a virtual machine service 1020 such as a virtual server. One or more applications, such as application 1022 are also stored on storage device 1012, and are executable by computing device 1000.

Each of components 1002, 1004, 1006, 1008, 1010, and 1012 may be interconnected (physically, communicatively, and/or operatively) for inter-component communications, such as via one or more communications channels 1014. In some examples, communication channels 1014 include a system bus, network connection, inter-processor communication network, or any other channel for communicating data. Applications such as software application 1022 and operating system 1016 may also communicate information with one another as well as with other components in computing device 1000.

Processors 1002, in one example, are configured to implement functionality and/or process instructions for execution within computing device 1000. For example, processors 1002 may be capable of processing instructions stored in storage device 1012 or memory 1004. Examples of processors 1002 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 1012 may be configured to store information within computing device 1000 during operation. Storage device 1012, in some examples, is known as a computer-readable storage medium. In some examples, storage device 1012 comprises temporary memory, meaning that a primary purpose of storage device 1012 is not long-term storage. Storage device 1012 in some examples is a volatile memory, meaning that storage device 1012 does not maintain stored contents when computing device 1000 is turned off. In other examples, data is loaded from storage device 1012 into memory 1004 during operation. Examples of volatile memories include random access memories (RAM), dynamic random access memories (DRAM), static random access memories (SRAM), and other forms of volatile memories known in the art. In some examples, storage device 1012 is used to store program instructions for execution by processors 1002. Storage device 1012 and memory 1004, in various examples, are used by software or applications running on computing device 1000 such as software application 1022 to temporarily store information during program execution.

Storage device 1012, in some examples, includes one or more computer-readable storage media that may be configured to store larger amounts of information than volatile memory. Storage device 1012 may further be configured for long-term storage of information. In some examples, storage devices 1012 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 1000, in some examples, also includes one or more communication modules 1010. Computing device 1000 in one example uses communication module 1010 to communicate with external devices via one or more networks, such as one or more wireless networks. Communication module 1010 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 1000 uses communication module 1010 to wirelessly communicate with an external device such as via a public network.

Computing device 1000 also includes in one example one or more input devices 1006. Input device 1006, in some examples, is configured to receive input from a user through tactile, audio, or video input. Examples of input device 1006 include a touchscreen display, a mouse, a keyboard, a voice responsive system, video camera, microphone or any other type of device for detecting input from a user.

One or more output devices 1008 may also be included in computing device 1000. Output device 1008, in some examples, is configured to provide output to a user using tactile, audio, or video stimuli. Output device 1008, in one example, includes a display, a sound card, a video graphics adapter card, or any other type of device for converting a signal into an appropriate form understandable to humans or machines. Additional examples of output device 1008 include a speaker, a light-emitting diode (LED) display, a liquid crystal display (LCD or OLED), or any other type of device that can generate output to a user.

Computing device 1000 may include operating system 1016. Operating system 1016, in some examples, controls the operation of components of computing device 1000, and provides an interface from various applications such as software application 1022 to components of computing device 1000. For example, operating system 1016, in one example, facilitates the communication of various applications such as software application 1022 with processors 1002, communication unit 1010, storage device 1012, input device 1006, and output device 1008. Applications such as application 1022 may include program instructions and/or data that are executable by computing device 1000. These and other program instructions or modules may include instructions that cause computing device 1000 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some clamping embodiments may be described, at least in part, by the following numbered clauses or by any combination thereof:
Clause 1: A method of attaching an integrated circuit to a substrate, comprising: placing an integrated circuit on a substrate, the integrated circuit and the substrate separated by one or more spacers and by a plurality of solder balls; applying a clamping mechanism to bias the integrated circuit and substrate toward one another and coplanar to one another; heating the integrated circuit, the substrate, and the clamping mechanism to reflow the plurality of solder balls, the clamping mechanism biasing the integrated circuit and the substrate together against the one or more spacers and coplanar during the reflow; removing the heat applied to the integrated circuit, the substrate, and the clamping mechanism to cause the plurality of reflowed solder balls to solidify; and removing the clamping mechanism after the plurality of solder balls have solidified.
Clause 2: The method of clause 1, wherein the spacers comprise metal cores in one or more of the plurality of solder balls.
Clause 3: The method of clause 2, wherein the metal cores comprise copper balls.
Clause 4: The method of any of the aforementioned clauses, wherein the clamping mechanism comprises a spring-loaded biasing mechanism operable to continue to bias the integrated circuit and substrate toward one another as the integrated circuit and substrate move toward one another during reflow of the solder balls.
Clause 5: The method of any of the aforementioned clauses, further comprising using one or more heat sink holes in the substrate to align and/or attach the clamping mechanism to the substrate.
Clause 6: The method of any of the aforementioned clauses, further comprising underfilling the integrated circuit and the substrate after removing the heat to prevent movement of the integrated circuit relative to the substrate during subsequent reflow.
Clause 7: The method of any of the aforementioned clauses, wherein the integrated circuit comprises an integrated circuit package assembly.
Clause 8: The method of any of the aforementioned clauses, wherein the substrate comprises a printed circuit board.
Clause 9: The method of any of the aforementioned clauses, further comprising one or more alignment elements separating the integrated circuit and the substrate, the one or more alignment elements affixed to a first one of the integrated circuit or the substrate, the one or more alignment elements further operable to mate with an alignment hole in a second one of the integrated circuit or the substrate.
Clause 10: An integrated circuit mounting assembly, comprising: a top clamping element configured to engage an integrated circuit assembly; a bottom clamping element configured to engage a substrate; and a plurality of linking elements, each configured to engage the top clamping element and the bottom clamping element and to bias the top clamping element and the bottom clamping element toward one another, thereby biasing the integrated circuit assembly toward the substrate and flattening the integrated circuit assembly or the substrate, or a combination thereof.
Clause 11: The assembly of clause 10, further comprising an elastic member configured to bias the top clamping element toward the bottom clamping element while allowing movement of the top clamping element relative to the bottom clamping element.
Clause 12: The assembly of any of clauses 10-11, wherein the top clamping element is configured to engage a stiffener comprising a part of the integrated circuit assembly.
Clause 13: The assembly of any of clauses 10-12, wherein the bottom clamping element comprises a thermal dissipation element support bracket.
Clause 14: The assembly of any of clauses 10-13, wherein the linking elements are configured to pass through thermal dissipation element support holes in the substrate.
Clause 15: The assembly of any of clauses 10-14, further comprising a plurality of spacers maintaining a desired distance between the integrated circuit assembly and the substrate when the top clamping element and the bottom clamping element are biased toward one another.
Clause 16: The assembly of clause 15, wherein the plurality of spacers comprise solder-coated metal balls.
Clause 17: The assembly of any of clauses 10-16, further comprising at least one alignment element configured to align the integrated circuit assembly and the substrate when the top clamping element and the bottom clamping element are biased toward one another.
Clause 18: The assembly of clause 17, further comprising a ball grid array of solder balls configured to physically and electrically couple the integrated circuit assembly to the substrate, the integrated circuit mounting assembly configured to bias the top clamping element and the bottom clamping element toward one another during reflow of the ball grid array of solder balls.
Clause 19: A method of attaching an integrated circuit to a substrate, comprising: applying a clamping mechanism to bias the integrated circuit and substrate toward one another and coplanar to one another; and reflowing the integrated circuit to electrically and physically attach it to the substrate by heating the integrated circuit, the substrate, and the clamping mechanism.
Clause 20: The method of clause 19, further comprising separating the integrated circuit and substrate with a plurality of standoffs before applying the clamping mechanism.

Some alignment embodiments may be described, at least in part, by the following numbered clauses and by any combination thereof:
Clause 1: An integrated circuit assembly, comprising: an integrated circuit; a substrate; a plurality of solder balls operable to electrically and physically couple the integrated circuit to the substrate; and a plurality of alignment elements operable to align the integrated circuit and the substrate with respect to one another during reflow of the plurality of solder balls.
Clause 2: The assembly of clause 1, wherein the alignment elements comprise one or more pins affixed to a first of the integrated circuit and the substrate and one or more corresponding holes formed within a second of the integrated circuit and the substrate.
Clause 3: The assembly of clause 2, wherein the one or more pins are conical in shape.
Clause 4: The assembly of any of clauses 2-3, wherein the one or more pins comprise a standoff portion having a greater diameter than an alignment portion, the standoff portion operable to maintain a desired spacing between the integrated circuit and the substrate.
Clause 5: The assembly of any of the aforementioned clauses, wherein the one or more alignment features are located remote from a corner of the integrated circuit.
Clause 6: The assembly of any of the aforementioned clauses, wherein the one or more alignment features are operable to align the integrated circuit and the substrate within a tolerance of one quarter a pitch of the plurality of solder balls.
Clause 7: The assembly of any of the aforementioned clauses, further comprising one or more standoffs separating the integrated circuit from the substrate, the one or more standoffs comprising a metal that does not melt during solder reflow.
Clause 8: The assembly of clause 7, wherein the one or more standoffs comprise a metal core in one or more of the plurality of solder balls.
Clause 9: The assembly of clause 8, wherein the metal core comprises a copper core.
Clause 10: The assembly of any of the aforementioned clauses, further comprising a clamping mechanism operable to bias the integrated circuit and substrate toward one another and coplanar to one another during solder reflow.
Clause 11: A method of aligning an integrated circuit assembly and a substrate, comprising: mating one or more alignment elements on an integrated circuit assembly with one or more alignment elements on a substrate, the one or more alignment elements operable when mated to align the integrated circuit assembly with the substrate during reflow of a plurality of solder balls operable to electrically and physically couple the integrated circuit to the substrate.
Clause 12: The method of clause 11, wherein the alignment elements comprise one or more pins affixed to a first of the integrated circuit and the substrate and one or more corresponding holes formed within a second of the integrated circuit and the substrate.
Clause 13: The method of clause 12, wherein the one or more pins comprise a standoff portion having a greater diameter than an alignment portion, the standoff portion operable to maintain a desired spacing between the integrated circuit and the substrate.
Clause 14: The method of any of clauses 11-13, wherein the one or more alignment features are located remote from a corner of the integrated circuit assembly.
Clause 15: The method of any of clauses 11-14, wherein the one or more alignment features are operable to align the integrated circuit assembly and the substrate within a tolerance of one-quarter a pitch of the plurality of solder balls.
Clause 16: The method of any of clauses 11-15, further comprising one or more spacers separating the integrated circuit assembly from the substrate, the one or more spacers comprising a metal that does not melt during solder reflow.
Clause 17: The method of clause 16, wherein the one or more spacers comprise a metal core that does not melt during solder reflow in one or more of the plurality of solder balls.
Clause 18: The method of any of clauses 11-17, further comprising biasing the integrated circuit and substrate toward one another and coplanar to one another during solder reflow using a clamping mechanism.
Clause 19: An integrated circuit alignment assembly, comprising: one or more first alignment elements comprising a part of an integrated circuit assembly operable to mate with one or more second alignment elements of a substrate, the one or more first alignment elements and one or more second alignment elements operable to align the integrated circuit assembly with the substrate when mated.
Clause 20: The integrated circuit alignment assembly of clause 19, further comprising a plurality of spacers operable to maintain a desired space between the integrated circuit assembly and the substrate during a reflow process to physically and electrically couple the integrated circuit assembly to the substrate.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. A method of attaching an integrated circuit to a substrate, comprising:
placing an integrated circuit on a substrate, the integrated circuit and the substrate separated by one or more spacers and by a plurality of solder balls;
applying a clamping mechanism to bias the integrated circuit and substrate toward one another and coplanar to one another;
heating the integrated circuit, the substrate, and the clamping mechanism to reflow the plurality of solder balls, the clamping mechanism biasing the integrated circuit and the substrate together against the one or more spacers and coplanar during the reflow;
removing the heat applied to the integrated circuit, the substrate, and the clamping mechanism to cause the plurality of reflowed solder balls to solidify; and
removing the clamping mechanism after the plurality of solder balls have solidified.

2. The method of claim 1, wherein the spacers comprise metal cores in one or more of the plurality of solder balls.

3. The method of claim 2, wherein the metal cores comprise copper balls.

4. The method of claim 1, wherein the clamping mechanism comprises a spring-loaded biasing mechanism operable to continue to bias the integrated circuit and substrate toward one another as the integrated circuit and substrate move toward one another during reflow of the solder balls.

5. The method of claim 1, further comprising using one or more heat sink holes in the substrate to align and/or attach the clamping mechanism to the substrate.

6. The method of claim 1, further comprising underfilling the integrated circuit and the substrate after removing the heat to prevent movement of the integrated circuit relative to the substrate during subsequent reflow.

7. The method of claim 1, wherein the integrated circuit comprises an integrated circuit package assembly.

8. The method of claim 1, wherein the substrate comprises a printed circuit board.

9. The method of claim 1, further comprising one or more alignment elements separating the integrated circuit and the substrate, the one or more alignment elements affixed to a first one of the integrated circuit or the substrate, the one or more alignment elements further operable to mate with an alignment hole in a second one of the integrated circuit or the substrate.

10. An integrated circuit mounting assembly, comprising:
a top clamping element configured to engage an integrated circuit assembly;
a bottom clamping element configured to engage a substrate; and
a plurality of linking elements, each configured to engage the top clamping element and the bottom clamping element and to bias the top clamping element and the bottom clamping element toward one another, thereby biasing the integrated circuit assembly toward the substrate and flattening the integrated circuit assembly or the substrate, or a combination thereof.

11. The integrated circuit mounting assembly of claim 10, further comprising an elastic member configured to bias the top clamping element toward the bottom clamping element while allowing movement of the top clamping element relative to the bottom clamping element.

12. The integrated circuit mounting assembly of claim 10, wherein the top clamping element is configured to engage a stiffener comprising a part of the integrated circuit assembly.

13. The integrated circuit mounting assembly of claim 10, wherein the bottom clamping element comprises a thermal dissipation element support bracket.

14. The integrated circuit mounting assembly of claim 10, wherein the linking elements are configured to pass through thermal dissipation element support holes in the substrate.

15. The integrated circuit mounting assembly of claim 10, further comprising a plurality of spacers maintaining a desired distance between the integrated circuit assembly and the substrate when the top clamping element and the bottom clamping element are biased toward one another.

16. The integrated circuit mounting assembly of claim 15, wherein the plurality of spacers comprise solder-coated metal balls.

17. The integrated circuit mounting assembly of claim 10, further comprising at least one alignment element configured to align the integrated circuit assembly and the substrate when the top clamping element and the bottom clamping element are biased toward one another.

18. The integrated circuit mounting assembly of claim 17, further comprising a ball grid array of solder balls configured to physically and electrically couple the integrated circuit assembly to the substrate, the integrated circuit mounting assembly configured to bias the top clamping element and the bottom clamping element toward one another during reflow of the ball grid array of solder balls.

19. A method of attaching an integrated circuit to a substrate, comprising:
applying a clamping mechanism to bias the integrated circuit and substrate toward one another and coplanar to one another; and
reflowing the integrated circuit to electrically and physically attach it to the substrate by heating the integrated circuit, the substrate, and the clamping mechanism.

20. The method of claim 19, further comprising separating the integrated circuit and substrate with a plurality of standoffs before applying the clamping mechanism.
